(19) United States
(12) Patent Application Publication
(10) Pub. No.: US 2008/0210970 A1
(43) Pub. Date: Sep. 4, 2008

(54) Fabrication of Conductive Metal Layer on Semiconductor Devices

(75) Inventors: Xuejun Kang, Singapore (SG); Daike Wu, Singapore (SG); Edward Robert Perry, Sedone, AZ (US); Shu Yuan, Singapore (SG)

Correspondence Address: BLAKELY SOKOLOFF TAYLOR & ZAFMAN LLP, 1279 OAKMEAD PARKWAY, SUNNYVALE, CA, 94085-4040, US

(73) Assignee: TINGGI TECHNOLOGIES PRIVATE LIMITED, Science Park 1 (SG)

(21) Appl. No.: 10/572,524

(22) PCT Filed: Sep. 19, 2003
(86) PCT No.: PCT/SG2003/000222

§ 371 Date: Sep. 11, 2007

(51) Int. Cl. H01L 33/00; H01L 21/00

(52) U.S. Cl. 257/99; 438/22; 257/E33.063

(57) ABSTRACT

A method for fabrication of a light emitting device on a substrate, the light emitting device having a wafer with multiple epitaxial layers and an ohmic contact layer on the epitaxial layers remote from the substrate. The method includes the steps: (a) applying to the ohmic contact layer a seed layer of a thermally conductive metal; (b) electroplating a relatively thick layer of the conductive metal on the seed layer; and (c) removing the substrate. A corresponding light emitting device is also disclosed. The light emitting device is a GaN light emitting diode or laser diode.

### FIELD OF THE INVENTION

The present invention relates to the fabrication of a conductive metal layer on semiconductor devices and refers particularly, though not exclusively, to the plating of a relatively thick conductive metal layer on light emitting devices. The relatively thick conductive layer may be for heat conduction and/or electrical conduction and/or for mechanical support

### BACKGROUND TO THE INVENTION

As semiconductor devices have developed there has been a considerable increase in their operational speed, and a reduction in overall size. This is causing a major problem of heat build-up in the semiconductor devices. Therefore, heat sinks are being used to help dissipate the heat from the semiconductor device. Such heat sinks are normally fabricated separately from the semiconductor device and are normally adhered to the semiconductor device just prior to encapsulation.

There have been many proposals for the electroplating of copper onto surfaces of semiconductor devices during their fabrication, particularly for use as interconnects.

The majority of current semiconductor devices are made from semiconductor materials based on silicon (Si), gallium arsenide (GaAs), and indium phosphide (InP). Compared to such electronic and optoelectronic devices, GaN devices have many advantages. The major intrinsic advantages that GaN have are:

TABLE 1

| | | Band Gap | BFOM | |
|---|---|---|---|---|
| | | (eV)/ | (power | Maximum |
| Semi- | Mobility μ | wavelength | transistor | Temperature |
| conductor | (cm²/Vs) | (nm) | merit) | (C.) |
| Si | 1300 | 1.1/1127 | 1.0 | 300 |
| GaAs | 5000 | 1.4/886 | 9.6 | 300 |
| GaN | 1500 | 3.4/360 | 24.6 | 700 |

BFOM: Baliga's figure of merit for power transistor performance A shorter wavelength corresponds to a higher DVD/CD capacity.

From Table 1, it can be seen that GaN has the highest band gap (3.4 eV) among the given semiconductors. Thus, it is called a wide band gap semiconductor. Consequently, electronic devices made of GaN operate at much higher power than Si and GaAs and InP devices.

For semiconductor lasers, GaN lasers have a relatively short wavelength. If such lasers are used for optical data storage, the shorter wavelength may lead to a higher capacity. GaAs lasers are used for the manufacture of CD-ROMs with a capacity of about 670 MB/disk. AlGaInP lasers (also based on GaAs) are used for the latest DVD players with a capacity of about 4.7 GB/disk. GaN lasers in the next-generation DVD players may have a capacity of 26 GB/disk.

GaN devices are made from GaN wafers that are typically multiple GaN-related epitaxial layers deposited on a sapphire substrate. The sapphire substrate is usually two inches in diameter and acts as the growth template for the epitaxial layers. Due to lattice mismatch between GaN-related materials (epitaxial films) and sapphire, defects are generated in the epitaxial layers. Such defects cause serious problems for GaN lasers and transistors and, to a lesser extent, for GaN LEDs.

There are two major methods of growing epitaxial wafers: molecular beam epitaxy (MBE), and metal organic chemical vapour deposition (MOCVD). Both are widely used.

Conventional fabrication processes usually include these major steps: photolithography, etching, dielectric film deposition, metallization, bond pad formation, wafer inspection/testing, wafer thinning, wafer dicing, chip bonding to packages, wire bonding and reliability testing.

Once the processes for making LEDs are completed at the full wafer scale, it is then necessary to break the wafer into individual LED chips or dice. For GaN wafers grown on sapphire substrates, this “dicing” operation is a major problem as sapphire is very hard. The sapphire first has to be thinned uniformly from about 400 microns to about 100 microns. The thinned wafer is then diced by diamond scriber, sawed by a diamond saw or by laser grooving, followed by scribing with diamond scribers. Such processes limit throughput, cause yield problems and consume expensive diamond scribers/saws.

Known LED chips grown on sapphire substrates require two wire bonds on top of the chip. This is necessary because sapphire is an electrical insulator and current conduction through the 100-micron thickness is not possible. Since each wire bond pad takes about 10-15% of the wafer area, the second wire bond reduces the number of chips per wafer by about 10-15% as compared to single-wire bond LEDs grown on conducting substrates. Almost all non-GaN LEDs are grown on conducting substrates and use one wire bond. For packaging companies, two wire bonding reduces packaging yield, requires modification of one-wire bonding processes, reduces the useful area of the chip, and complicates the wire bonding process and thus lowers packaging yield.

Sapphire is not a good thermal conductor. For example, its thermal conductivity at 300K (room temperature) is 40 W/Km. This is much smaller than copper's thermal conductivity of 380 W/Km. If the LED chip is bonded to its package at the sapphire interface, the heat generated in the active region of the device must flow through 3 to 4 microns of GaN and 100 microns of sapphire to reach the package/heat sink. As a consequence, the chip will run hot affecting both performance and reliability.

For GaN LEDs on sapphire, the active region where light is generated is about 3-4 micron from the sapphire substrate.

### SUMMARY OF THE INVENTION

In accordance with a preferred form of the present invention, there is provided a method for fabrication of a light emitting device on a substrate, the light emitting device having wafer with multiple epitaxial layers and a first ohmic contact layer on the epitaxial layers remote from the substrate; the method including the steps:
(a) applying to the first ohmic contact layer a seed layer of a thermally conductive metal;
(b) electroplating a relatively thick layer of the thermally conductive metal on the seed layer; and
(c) removing the substrate.

Prior to the seed layer being applied, the first ohmic contact layer may be coated with an adhesion layer. Before the electroplating of the relatively thick layer the seed layer may be patterned with photoresist patterns; the relatively thick layer being electroplated between the photoresists.

The seed layer may be electroplated without patterning and with patterning being performed subsequently. Patterning may be by photoresist patterning and then wet etching. Alternatively, it may be by laser beam micro-machining of the relatively thick layer.

Between steps (b) and (c) there may be performed the additional step of annealing the wafer to improve adhesion.

Preferably, the photoresists are of a height of at least 50 micrometers, and have a thickness in the range 3 to 500 micrometers. More preferably, the photoresists have a spacing of 300 micrometers.

The relatively thick layer may be of a height no greater that the photoresist height. The relatively thick layer may be electroplated to a height above the photoresist and be subsequently thinned. Thinning may be by polishing.

After step (c) there may be included an extra step of forming on a surface of the epitaxial layers opposite the first ohmic contact layer a second ohmic contact layer for electrical contacts, the second ohmic contact layer being one of opaque, transparent, and semitransparent, and may be either blank or patterned. Ohmic contact formation and subsequent process steps may subsequently be carried out The subsequent process steps may include deposition of wire bond pads. The exposed epitaxial layer may be cleaned and etched before the second contact layer is deposited onto it. The second contact layer may not cover the whole area of the epitaxial layers.

The light emitting devices may be tested on the wafer, and the wafer may be subsequently separated into individual devices.

The light emitting devices may be fabricated without one or more of: lapping, polishing and dicing.

The first ohmic contact layers may be on p-type layers of the epitaxial layers; and the second contact layer may be ohmic and may be formed on n-type layers of the expitaxial layers.

After Step (c), dielectric films may be deposited on the epitaxial layers. Openings may then be cut in the dielectric and first ohmic contact layers and bond pads deposited on the epitaxial layers. Alternatively, after step (c), electroplating of a thermally conductive metal (or other material) on the epitaxial layers may be performed.

The invention is also directed to a light emitting device fabricated by the above method. The light emitting device may be a light emitting diode or a laser diode.

In a further aspect, the present invention provides a light emitting device comprising epitaxial layers, first ohmic contact layers on a first surface of the epitaxial layers, a relatively thick layer of a thermally conductive metal on the first ohmic contact layer, and a second ohmic contact layer on a second surface of the epitaxial layers; the relatively thick layer being applied by electroplating.

There may be an adhesive layer on the first ohmic contact layers between the first ohmic contact layers and the relatively thick layer.

The relatively thick layer may be at least 50 micrometers thick; and the second ohmic contact layer may be a thin layer in the range of from 3 to 500 nanometers. The second ohmic contact layer may be transparent, semi-transparent or opaque; and may include bonding pads.

For all forms of the invention, the thermally conductive metal may be copper. There may be a seed layer of the thermally conductive metal applied to the adhesive layer.

To assist in improving light output, the first ohmic contact layers, at the interface with the epitaxial layers, may also act as a mirror. Any light passing through the first ohmic contact layers may be reflected by the adhesion layer.

The light emitting device may be one of a light emitting diode, and a laser diode.

In yet another form, there is provided a light emitting device comprising epitaxial layers, a first ohmic contact layer on a first surface of the epitaxial layers, an adhesive layer on the first ohmic contact layer, and a seed layer of a thermally conductive metal on the adhesive layer, the first ohmic contact layer at its interface with the epitaxial layer, acting as a mirror.

There may be further included a relatively thick layer of the thermally conductive metal on the seed layer.

A second ohmic contact layer may be provided on a second surface of the epitaxial layers; the second ohmic contact layer being a thin layer in the range of from 3 to 500 nanometers. The second ohmic contact layer may comprise bonding pads; and may be one of opaque, transparent, and semi-transparent.

The thermally conductive metal may comprise copper; and the epitaxial layers may comprise GaN-related layers.

In a penultimate form, the present invention provides a method of fabrication of a light emitting device, the method including the steps:
(a) on a substrate with a wafer comprising multiple GaN-related epitaxial layers, forming a first ohmic contact layer on a first surface of the wafer;
(b) removing the substrate from the wafer, and
(c) forming a second ohmic contact layer on a second surface of the wafer, the second ohmic contact layer having bonding pads formed thereon.

The second ohmic contact layer may be for light emission; and may be opaque, transparent, or semi-transparent. The second ohmic contact layer may be blank or patterned.

In a final form, there is provided a light emitting device fabricated by the above method.

### BRIEF DESCRIPTION OF THE DRAWINGS

In order that the invention may be better understood and readily put into practical effect there shall now be described by way of non-limitative example only a preferred embodiment of the present invention, the description being with reference to the accompanying illustrative (and not to scale) drawings in which:

FIG. 1 is a schematic representation of a light emitting device at a first stage in the fabrication process;

FIG. 2 is a schematic representation of the light emitting device of FIG. 1 at a second stage in the fabrication process;

FIG. 3 is a schematic representation of the light emitting device of FIG. 1 at a third stage in the fabrication process;

FIG. 4 is a schematic representation of the light emitting device of FIG. 1 at a fourth stage in the fabrication process;

FIG. 5 is a schematic representation of the light emitting device of FIG. 1 at a fifth stage in the fabrication process;

FIG. 6 is a schematic representation of the light emitting device of FIG. 1 at a sixth stage in the fabrication process;

FIG. 7 is a schematic representation of the light emitting device of FIG. 1 at the seventh stage in the fabrication process; and

FIG. 8 is a flow chart of the process.

### DETAILED DESCRIPTION OF THE PREFERRED EMBODIMENT

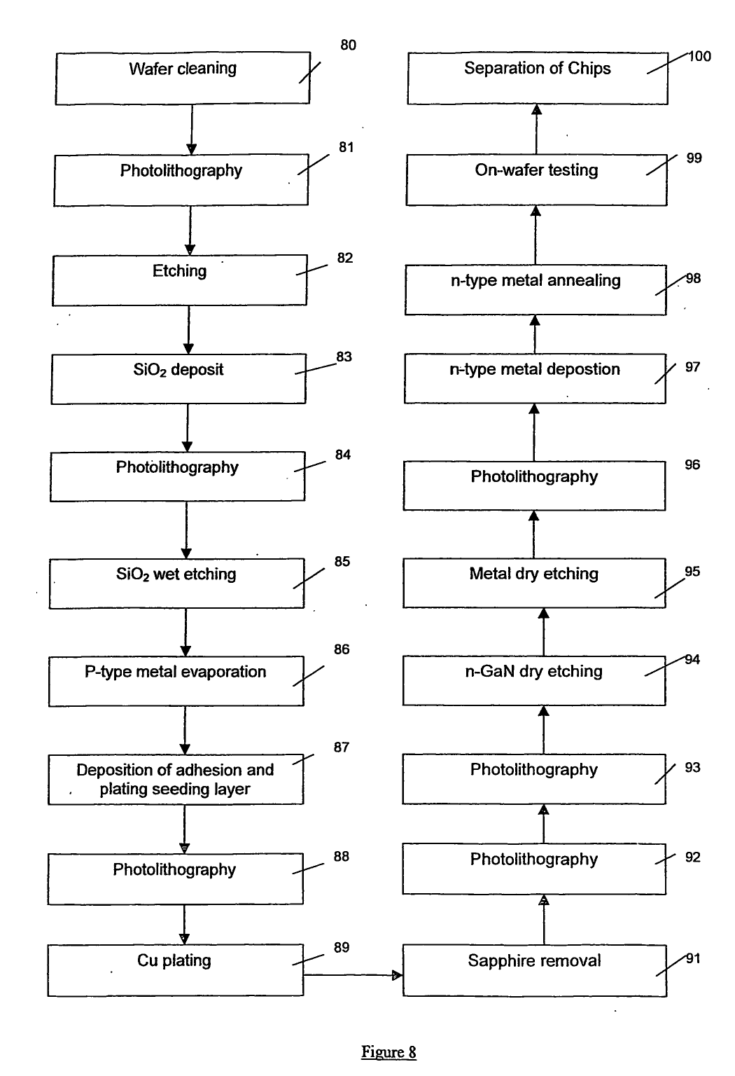

For the following description, the reference numbers in brackets refer to the process steps in FIG. 8.

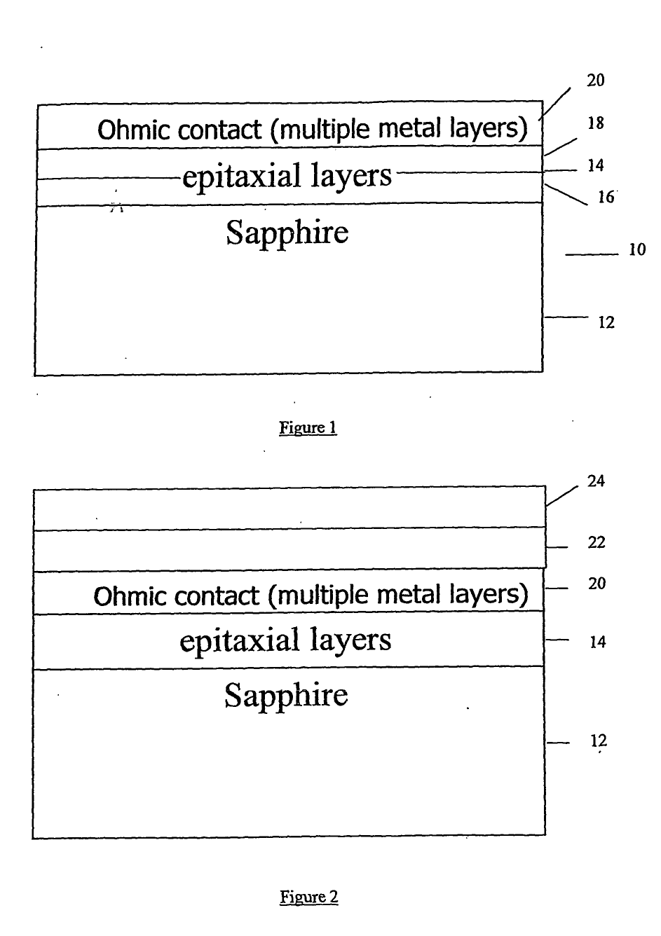

To refer to FIG. 1, there is shown the first step in the process—the metallization on the p-type surface of the wafer 10.

The wafer 10 is an epitaxial wafer with a substrate and a stack of multiple epitaxial layers 14 on it The substrate 12 can be, for example, sapphire, GaAs, InP, Si, and so forth. Henceforth a GaN sample having GaN layer(s) 14 on sapphire substrate 12 will be used as an example. The epitaxial layers 14 (often called epilayers) are a stack of multiple layers, and the lower part 16 (which is grown first on the substrate) is usually n-type layers and the upper part 18 is often p-type layers.

On GaN layers 14 is an ohmic contact layer 20 having multiple metal layers. To ohmic contact layer 20 is added an adhesion layer 22, and a thin copper seed layer 24 (FIG. 2) (step 88) of a thermally conductive metal such as, for example, copper. The thermally conductive metal is preferably also electrically conductive. The stack of adhesion layers may be annealed after formation.

The ohmic layer 20 may be a stack of multiple layers deposited and annealed on the epitaxial surface. It may not be part of the original wafer. For GaN, GaA, and InP devices, the epitaxial wafer often contains an active region that is sandwiched between n-type and p-type semiconductors. In most cases the top layer is p-type. For silicon devices, epitaxial layers may not be used, but just the wafer.

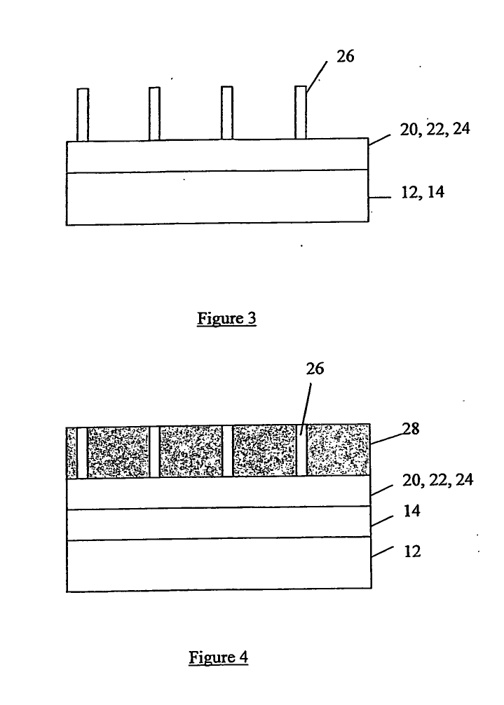

As shown in FIG. 3, using standard photolithography (89), the thin copper seed layer 24 is patterned with relatively thick photoresists 26. The photoresist patterns 26 are of a height of at least 50 micrometers, preferably in the range 50 to 300 micrometers, more preferably 200 micrometers; and with a thickness of about 3 to 500 micrometers. They are preferably separated from each other by a spacing of about 300 micrometers, depending on the design of the final chips. The actual pattern depends on device design.

A patterned layer 28 of copper is then electroplated onto layer 24 (90) between photoresists 26 to form a heat sink that forms a part of the substrate. The copper layer 28 is preferably of a height no greater than that of the photoresists 26 and is therefore of the same or lesser height than the photoresists 26. However, the copper layer 28 may be of a height greater than that of the photoresists 26. In such a case, the copper layer 28 may be subsequently thinned to be of a height no greater than that of the photoresists 26. Thinning may be by polishing or wet etching. The photoresists 26 may or may not be removed after the copper plating. Removal may be by a standard and known method such as, for example, resin in the resist stripper solution, or by plasma aching.

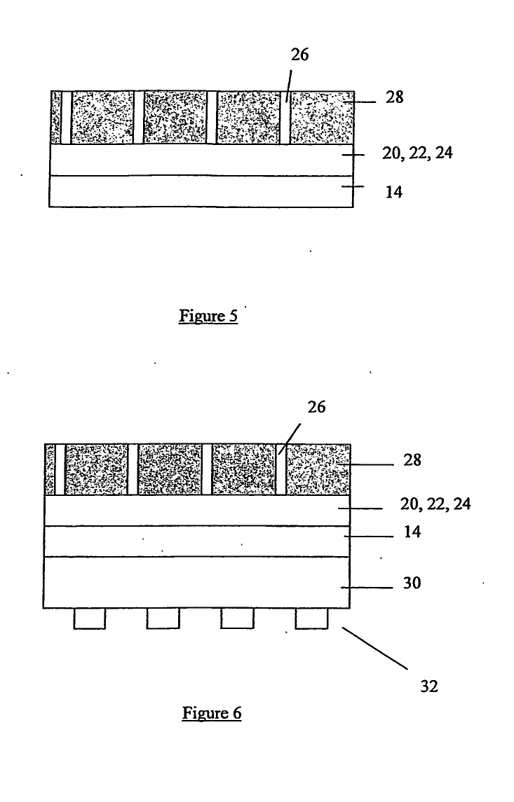

Depending on the device design, processing of the epitaxial layers 14 follows using standard processing techniques such as, for example, cleaning (80), lithography (81), etching (82), device isolation (83), passivation (84), metallization (85), thermal processing (86), and so forth. (FIG. 4). The wafer 10 is then annealed (87) to improve adhesion.

The epitaxial layer 14 is usually made of n-type layers 16 on the original substrate 12; and p-type layers on the original top surface 18 which is now covered with the ohmic 20, adhesion 22 and copper seed layers 24 and the electroplated thick copper layer 28.

In FIG. 5, the original substrate layer 12 is then removed (91) using, for example, the method of Kelly [M. K. Kelly, O. Ambacher, R. Dimitrov, R. Handschuh, and M. Stutzmann, phys. stat sol. (a) 159, R3 (1997)]. The substrate may also be removed by polishing or wet etching.

FIG. 6 is the penultimate step and is particularly relevant for light emitting diodes where a second ohmic contact layer 30 is added beneath epitaxial layers 14 for light emission. Bonding pads 32 are also added. The second ohmic contact layer 30 is preferably transparent or semi-transparent. It is more preferably a thin layer and may be in the range of 3 to 50 nm thick.

Prior to adding second ohmic contact layer 30, known preliminary processes may be performed. These may be, for example, photolithography (92, 93), dry etching (94, 95), and photolithography (96).

Annealing (98) may follow the deposition of second ohmic contact layer 30.

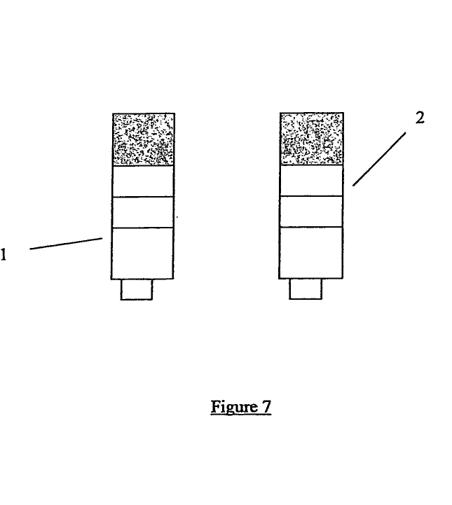

The chips/dies are then tested (99) by known and standard methods. The chips/dies can then be separated (100) (FIG. 7) into individual devices/chips 1 and 2 without lapping/polishing the substrate, and without dicing. Packaging follows by standard and known methods

The top surface of the epitaxial layer 14 is preferably in the range of about 0.1 to 2.0 microns, preferably about 0.3 microns, from the active region. As the active region of the LED chip in this configuration is close to a relatively thick copper pad 28, the rate of heat removal is improved over the sapphire configuration.

Additionally or alternatively, the relatively thick layer 28 may be used to provide mechanical support for the chip. It may also be used to provide a path for heat removal from the active region of the light emitting device chip, and may also be used for electrical connection.

The plating step is performed at the wafer level (i.e., before the dicing operation) and may be for several wafers at the one time.

The fabrication of GaN laser diodes is similar to the fabrication of GaN LEDs, but more steps may be involved. One difference is that GaN laser diodes require mirror formation during the fabrication. Using sapphire as the substrate compared to the method without sapphire as the substrate, the mirror formation is much more difficult and the quality of the mirror is generally worse.

After sapphire is removed, the laser will have better performance. A typical GaN laser epitaxial wafer structure is shown in Table 2.

For standard commercial GaN LEDs, about 5% light generated in the m semiconductor is emitted. Various ways have been developed to extract more light out from the chip in non-GaN LEDs (especially red LEDs based on AlGaInP, not GaN).

The first ohmic contact layer 20, being metal and relatively smooth, is quite shinny and therefore highly reflective of light. As such the first ohmic contact layer 20, at its interface with the epitaxial layers 14, also acts as a reflective surface, or mirror, to improve light output

Although the preferred embodiments refer to the use of copper, any other platable material may be used provided it is electrically and/or heat conductive, or provides the mechanical support for the light emitting device.

Whilst there has been described in the foregoing description a preferred form of the present invention, it will be understood by those skilled in the technology that many variations or modifications in design, construction or operation may be made without departing from the present invention.

1. A method for fabrication of a light emitting device on substrate, the light emitting device having a wafer with multiple epitaxial layers and a first ohmic contact layer on the epitaxial layers remote from the substrate; the method including:
(a) applying to the ohmic first contact layer a seed layer of a thermally conductive metal;
(b) electroplating a relatively thick layer of the thermally conductive metal on the seed layer; and
(c) removing the substrate.

2. A method as claimed in claim 1, wherein the first ohmic contact layer is coated with an adhesion layer prior to application of the seed layer.

3. A method as claimed in claim 1, wherein the seed layer is patterned with photoresist patterns before the electroplating step (b).

4. A method as claimed in claim 3, wherein the electroplating of the relatively thick layer is between the photoresist patterns.

5. A method as claimed in claim 1, wherein between steps (b) and (c) there is performed the additional step of annealing the wafer to improve adhesion.

6. A method as claimed in claim 3 or, wherein the photoresist patterns are of a height of at least 50 micrometers, a thickness in the range of 3 to 500 micrometers, and a spacing of 300 micrometers.

7-8. (canceled)

9. A method as claimed in claim 1, wherein the seed layer is electroplated in step (b) without patterning, patterning being performed subsequently.

10. A method as claimed in claim 9, wherein patterning is by photoresist patterning and then wet etching, or by laser beam micro-machining of the relatively thick layer.

11. (canceled)

12. A method as claimed in claim 3, wherein the relatively thick layer is of a height no greater than the photoresist height, or is electroplated to a height greater than the photoresist and is subsequently thinned.

13. (canceled)

14. A method as claimed in claim 12, wherein thinning is by polishing.

15. A method as claimed in claim 1, wherein after step (c) there is included an extra step of forming on a second surface of the epitaxial layers a second ohmic contact layer, the second ohmic contact layer being selected from the group consisting of: opaque, transparent, and semi-transparent.

16. A method as claimed in claim 15, wherein the second ohmic contact layer is one of blank and patterned, wherein bonding pads are formed on the second ohmic contact layer.

17. (canceled)

18. A method as claimed in claim 1, wherein after step (c) ohmic contact formation and subsequent process steps are carried out, the subsequent process steps including deposition of wire bond pads.

19. A method as claimed in claim 18, wherein the exposed epitaxial layer is cleaned and etched before the second ohmic contact layer is deposited.

20. A method as claimed in claim 15, wherein the second ohmic contact layer does not cover the whole area of the second surface of the epitaxial layers.

21. A method as claimed in claim 15, wherein after forming the second ohmic contact layer there is included testing of the light emitting devices on the wafer, and separating the wafer into individual devices.

22. (canceled)

23. A method as claimed in claim 1, wherein the light emitting devices are fabricated without one or more selected from the group consisting of: lapping, polishing and dicing.

24. A method as claimed in claim 1, wherein the first ohmic contact layers are on p-type layers of the epitaxial layers.

25. A method as claimed in claim 15, wherein the second ohmic contact layer is formed on n-type layers of the expitaxial layers.

26. A method as claimed in claim 1, wherein after step (c), dielectric films are deposited on the epitaxial layers and openings are cut in the dielectric films and second ohmic contact layers and bond pads deposited on the epitaxial layers.

27. A method as claimed in claim 1, wherein after step (c), electroplating of a thermally conductive metal on the epitaxial layers is performed.

28. A method as claimed in claim 1, wherein the thermally conductive metal comprises copper and the epitaxial layers comprise multiple GaN-related layers.

29. A light emitting diode fabricated by the method of claim 1.

30. A laser diode fabricated by the method of claim 1.

31. A light emitting device comprising epitaxial layers, a first ohmic contact layer on a first surface of the epitaxial layers, a relatively thick layer of a thermally conductive metal on the first ohmic contact layer, and a second ohmic contact layer on a second surface of the epitaxial layers; the relatively thick layer being applied by electroplating.

32. A light emitting device as claimed in claim 31, wherein there is an adhesive layer on the first ohmic contact layer between the first ohmic contact layer and the relatively thick layer.

33. A light emitting device as claimed in claim 32, wherein there is a seed layer of the thermally conductive metal between the adhesive layer and the relatively thick layer.

34. A light emitting device as claimed in claim 31, wherein the relatively thick layer is at least 50 micrometers thick.

35. A light emitting device as claimed in claim 31, wherein the second ohmic contact layer is a thin layer in the range of from 3 to 500 nanometers.

36. A light emitting device as claimed in claim 31, wherein the second ohmic contact layer is selected from the group consisting of: opaque, transparent, and semi-transparent, and includes bonding pads.

37. (canceled)

38. A light emitting device as claimed in claim 31, wherein the thermally conductive metal is copper and the epitaxial layers comprise multiple GaN-related epitaxial layers.

39. A light emitting device as claimed claim 31, wherein the light emitting device is selected from the group consisting of: a light emitting diode, and a laser diode.

40. A light emitting device as claimed claim 31, wherein the first ohmic contact layer, at its interface with the epitaxial layers, is a mirror.

41. A light emitting device comprising epitaxial layers, a first ohmic contact layer on a first surface of the epitaxial layers, an adhesive layer on the first ohmic contact layer, a seed layer of a thermally conductive metal on the adhesive layer, and a relatively thick layer of the thermally conductive metal on seed layer; the first ohmic contact layer, at its interface with the epitaxial layers, is a mirror.

42. A light emitting device as claimed in claim 41, wherein the relatively thick layer is one or more selected from the group consisting of: a heat sink, an electrical connector, and a mechanical support.

43. A light emitting device as claimed in claim 41, further comprising a second ohmic contact layer on a second surface of the epitaxial layers, the second ohmic contact layer being a thin layer in the range of from 3 to 500 nanometers.

44. A light emitting device as claimed in claim 41, wherein the second ohmic contact layer comprises bonding pads and is selected from the group consisting of: opaque, transparent, and semi-transparent.

45. A light emitting device as claimed claim 41, wherein the thermally conductive metal comprises copper, and the epitaxial layers comprise GaN-related layers.

46. A light emitting device as claimed in claim 41, wherein the light emitting device is one of: a light emitting diode and a laser diode.

47. A method of fabrication of a light emitting device, the method including:
(a) on a substrate with a wafer comprising multiple GaN-related epitaxial layers, forming a first ohmic contact layer on a first surface of the wafer;
(b) removing the substrate from the wafer; and
(c) forming a second ohmic contact layer on a second surface of the wafer, the second ohmic contact layer having bonding pads formed thereon.

48. A method as claimed in claim 47, wherein the second ohmic contact layer is for light emission, and is selected from the group consisting of: opaque, transparent, and semi-transparent, the second ohmic contact layer being one of: blank, and patterned.

49. (canceled)

50. A light emitting device fabricated by the method of claim 47.

51. A light emitting device as claimed in claim 50, wherein the light emitting device is selected from the group consisting of: a light emitting diode, and a laser diode.
